(19) United States
(12) Patent Application Publication
(10) Pub. No.: US 2024/0013761 A1
(43) Pub. Date: Jan. 11, 2024

(54) SWAPPABLE AND CONFIGURABLE PRE-AMPLIFIER FOR A MUSICAL INSTRUMENT

(71) Applicant: Devon Bass, Boerne, TX (US)

(72) Inventor: Devon Smullen, Boerne, TX (US)

(73) Assignee: Devon Bass, Boerne, TX (US)

(21) Appl. No.: 18/196,157

(22) Filed: May 11, 2023

Related U.S. Application Data
(60) Provisional application No. 63/359,568, filed on Jul. 8, 2022.

(51) Int. Cl. G10H 3/18; G10H 1/46; G10H 1/00; H03F 3/183

(52) U.S. Cl. CPC G10H 3/181; G10H 1/46; G10H 3/186; G10H 1/0008; H03F 3/183; G10H 2220/461; H03F 2200/03

(57) ABSTRACT

A stringed instrument having a swappable and configurable pre-amplifier. pickups may detect vibrations in each string then transduce the vibration signal into an electrical signal. The electrical signal may be processed in differing manners including attenuation of amplitude, filtering across a frequency spectrum or otherwise altered according to one or more transfer functions embodied in a swappable and configurable pre-amplifier. In embodiments, this swappable pre-amplifier may be stored in a cavity that is accessible at the rear of the body of the stringed instrument. One may remove a first swappable pre-amplifier and connect a second swappable pre-amplifier. The pre-amplifiers may be electronically coupled to an audio output circuit of the musical instrument such that the electric signal from the pickups is altered according to the pre-amplifier profile.

### PRIORITY CLAIM

This application claims the benefit of U.S. Provisional Application No. 63/359,568, entitled “SWAPPABLE AND CONFIGURABLE PREAMPLIFIER FOR A MUSICAL INSTRUMENT” filed Jul. 8, 2022, which is incorporated by reference in its entirety herein for all purposes.

### BACKGROUND

Listening to and performing music is enjoyed by billions of people across the world and playing instruments has been a professional and recreational pursuit for many people who enjoy music. One particular subset of musical instruments that are prevalent in the music industry today include any number of stringed instruments, Stringed are musical instruments that produce sound from vibrating strings when the performer plays or sounds the strings in some manner. Musicians play some string instruments by plucking the strings with their fingers or a pick while others may be played by hitting the strings with a striker or hammer or by rubbing the strings with a bow. Typical stringed instruments include guitars and violins.

In most stringed instruments, the vibrations are transmitted to the body of the instrument, which often incorporates some sort of hollow or enclosed area. The body of the instrument also vibrates, along with the air inside it. The vibration of the body of the instrument and the enclosed hollow or chamber make the vibration of the string more audible to the performer and audience. The body of most string instruments is hollow, however, more modern stringed instruments, such as the electric guitar, utilize electric pickups that generate electronic amplification that allows for a solid wood body.

With all electric stringed instruments, electronic pickups, which may be initially described as small transducers disposed next to each string at a specific location on the body of the stringed instrument, are used to detect the vibrations of a plucked string and amplify the detected vibration into an electrical signal it in a desired way. As the pickups that are used are an electronic circuit, the nature of the detected and amplified signal may be greatly affected by the electronic components used in the electronic pickup circuit. However, as stringed instruments are manufactured, typically one or two sets of pickups are chosen and used for the instrument and cannot be easily changed to introduce new and different pickup profiles to the instrument.

### BRIEF DESCRIPTION OF THE DRAWINGS

Embodiments of the subject matter disclosed herein in accordance with the present disclosure will be described with reference to the drawings, in which:

FIG. 1 is a diagram of a conventional bass guitar having a conventional string pickup;

FIG. 2 is a view of a stringed instrument body having a cavity to enclose a first electronic pre-amplifier that can be changed to alter the electronic circuit that governs the electronic pickups of the stringed instrument according to an embodiment of the subject matter disclosed herein;

FIG. 3 is a view of a stringed instrument body having a cavity that exhibits a removed electronic pre-amplifier that governs the electronic pickups of the stringed instrument according to an embodiment of the subject matter disclosed herein

FIG. 4 is a view of a stringed instrument body having a cavity to enclose a second different electronic pre-amplifier that can be changed to alter the electronic circuit that governs the electronic pickups of the stringed instrument according to an embodiment of the subject matter disclosed herein;

FIG. 5 is diagram of an electronic pre-amplifier that may be swapped in and out of the cavity depicted in FIGS. 2-4 according to an embodiment of the subject matter disclosed herein;

FIG. 6 is a hybrid block and schematic diagram of the swappable electronic pre-amplifier system according to an embodiment of the subject matter disclosed herein; and

FIG. 7a-7c are diagrams of a different modular examples of swappable and configurable pre-amplifiers coupled through a 24-pin connector to the output audio chain of a musical instrument according to embodiments of the subject matter disclosed herein.

Note that the same numbers are used throughout the disclosure and figures to reference like components and features.

### DETAILED DESCRIPTION

The subject matter of embodiments disclosed herein is described here with specificity to meet statutory requirements, but this description is not necessarily intended to limit the scope of the claims. The claimed subject matter may be embodied in other ways, may include different elements or steps, and may be used in conjunction with other existing or future technologies. This description should not be interpreted as implying any particular order or arrangement among or between various steps or elements except when the order of individual steps or arrangement of elements is explicitly described.

Embodiments will be described more fully hereinafter with reference to the accompanying drawings, which form a part hereof, and which show, by way of illustration, exemplary embodiments by which the systems and methods described herein may be practiced. These systems and methods may, however, be embodied in many different forms and should not be construed as limited to the embodiments set forth herein; rather, these embodiments are provided so that this disclosure will satisfy the statutory requirements and convey the scope of the subject matter to those skilled in the art.

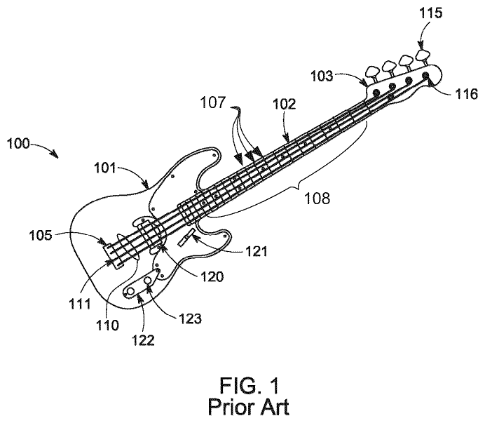

By way of an overview, the systems and methods discussed herein may be directed to a stringed instrument having at least one set of electronic or magnetic pickups associated, respectively, with each string in the stringed instrument. Collectively, the pickups detect vibration in each string as the string is plucked and then transduces the vibration signal into an electrical signal. The electrical signal may be processed in differing manners including attenuation of amplitude, filtering across a frequency spectrum or otherwise altered according to one or more transfer functions embodied in a swappable and configurable pre-amplifier. In embodiments, this swappable pre-amplifier may be stored in a cavity that is accessible at the rear of the body of the stringed instrument. In further embodiments, the swappable pre-amplifier may be mounted directly to the body of the instrument. One may remove a first swappable pre-amplifier and connect a second swappable pre-amplifier. The pre-amplifiers may be electronically coupled to an audio output circuit of the musical instrument such that the electric signal from the pickups is altered according to the pre-amplifier profile. Any number of different pre-amplifier profiles are contemplated as discussed below. These aspects and other novel features are discussed below with respect to FIGS. 1-7.

FIG. 1 is a diagram of a conventional bass guitar 100 having conventional means for implementing a pickup 120 next to strings 110 that are supported by a string bridge 105. Generally speaking, a pickup 120 is a transducer that captures, or senses mechanical vibrations produced by musical instruments, particularly stringed instruments such as an electric guitar or electric bass guitar. The sensed vibrations are then converted to electrical signals that may be amplified using an instrument amplifier to produce musical sounds through a loudspeaker. The signal from a pickup 120 can also be recorded directly into direct out systems in recording environments or other live sound environments. Most electric guitars and electric basses use magnetic pickups. Acoustic guitars, upright basses and fiddles often use a piezoelectric pickup.

As shown in FIG. 1, a conventional stringed instrument 100 is shown to illustrate the drawbacks of a typical stringed instruments wherein the single pickup 120 has but one single profile for how vibrations are translated into electrical signals. While FIG. 1 shows a bass guitar 100, a skilled artisan understands that these concepts illustrated here apply to any conventional stringed instrument. Further, the skilled artisan will also appreciate the application of the novel concepts discussed herein as also applying equally to any stringed instrument. As such, the reminder of this detailed description will remain focused on the application to a bass guitar 100 for brevity.

In FIG. 1, a bass guitar 100 is shown having four strings 110 attached thereto. The strings 110 are attached at a first anchor point 111 that is situated on an anchor bridge 105 disposed on the front face of a body 101. The other end of each string 110 is coupled to a second anchor point located at a head stock 103 at and end opposite the body 105 such that each string spans a neck 102. The strings 110 span the neck 102 over a fretboard that includes frets that a player may use to play different notes. The strings 110 are typically coupled to a tuning device 115 that is configured to rotate a respective nut when one actuates one of multiple tuning keys 116. That is, a first string 110 may be tightened or loosened between the string bridge 105 and a first tuning device 116 by turning a first tuning key 115. Likewise, a second string 110 may be tightened or loosened between the string bridge 105 and a second tuning device 116 and by turning a second tuning key 115, and so on.

Each string 110 spans the neck 102 which includes a fretboard having frets 107. As a player places one or more fingers on each string 110, the string may make contact with a fret 107 and then, when struck or plucked, vibrate at a frequency commensurate with the distance between the fret 107 and a string anchor point 111 that is part of the conventional string bridge 105. As a player's finger moves up and down the fretboard (e.g., neck 102), different frets 107 may be engaged for each string 110, thereby producing a different vibrations frequency (e.g., a different note). In stringed instruments, the length of the fretboard defines the instrument's scale length. A skilled artisan also understands that some stringed instruments are players without frets on a fretboard. Rather, the neck includes a fingerboard (e.g., a fretboard without frets) where a skilled artisan learns where to place fingers for producing desired notes without the precision of the fret.

Further, a typical bass guitar 100 will include an electronic pickup 120 that is configured to detect the vibration of each string and amplify the frequency of the sound. That is, a pickup 120 is, essentially a respective microphone disposed directly under each string 110. The audio signal detected may be further modified by circuitry controlled by a volume knob 122 and a tone control knob 123. Further yet, the bass guitar body 101 may include a pickguard 121.

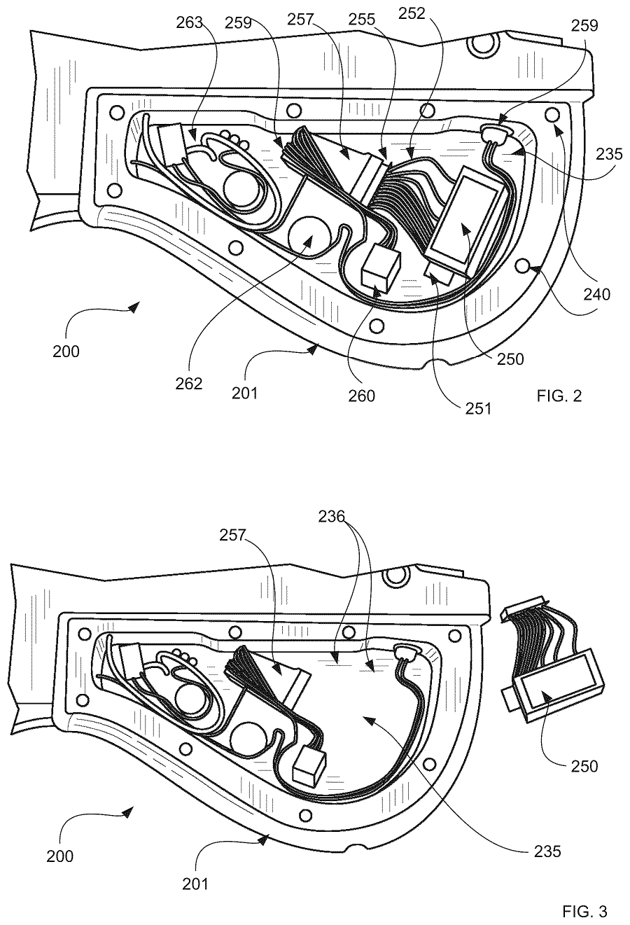

FIG. 2 is a view of a stringed instrument body portion 200 having a cavity 235 to enclose a first electronic pre-amplifier 250 that can be swapped or configured to alter the overall electronic circuit that governs the electronic pickups of the stringed instrument according to an embodiment of the subject matter disclosed herein. In this embodiment, the cavity 235 may include a removable cover plate (not shown) to encompass the electronic components therein. The cover plate may be held securely in place by a series of magnetetic fasteners 240 positioned at intervals along the edges of the exposed cavity 235. Thus, a person wishing to access the enclosed cavity needs to simply pry the cover plate away from the magnetic force holding the cover plate in place.

The electronic pre-amplifier 250 may be swappable in that additional (differently profiled) electronic pre-amplifiers (not shown here) may be inserted after the first electronic pre-amplifier 250 is removed, Each electronic pre-amplifier 250 includes an interface 255 that may include several different wiring connections (via harness 252) for providing electrical connections between the specific electronic components in the electronic pre-amplifier 250 and an interface mounting 257 for the electronic circuits of the audio output chain of the instrument. That is, the electronic pre-amplifier 250 is more readily swappable because of the 19-pin connector 255 disposed on the pre-amplifier 250 and designed to connect to the interface mounting 257 of the audio output chain.

Various third-party pre-amplifiers 250 may be manufactured. A non-exhaustive list of these manufactures includes Nordstrand™, Aguilar™, Bartolini™, Delano™, and DarkGlass™—all of which are well known in the industry. However, prior to the novel features disclosed herein, a person would have to engage a technician to hardwire a pre-amplifier 250 into an instrument. This typically involves paying a guitar technician to solder in the connections between electronic components such as potentiometers, filters, and output chains into said instrument (e.g., a universal interface did not exist in the instrument suitable for receiving numerous different pre-amplifiers 250. One innovation of the current swappable and configurable pre-amplifier 250 is the use of a universal wiring configuration for third-party pre-amplifiers 250 including a harness 252 and a pre-amplifier interface mounting 255. The harness may include wires that are electrically connected the mounting interface 255 that, in turn interfaces with a multi-pin quick connector 257 that is then electrically connected to various instrument components such as an output jack circuit 259, pick-ups circuits 263, a battery 262 and the like.

Such an interface mounting may also include a Digital Signal Processor (DSP) with a wireless communication module 260 (e.g., Bluetooth connectivity) to a remote device (e.g., a smartphone (not shown)) that may be used to configure different audio settings of the pre-amplifier 250 through an application executing on the remote device. Such a system enables a musician to quickly swap-out pre-amplifiers 250 thereby allowing the musician quick changes to the entire audio profile of their instrument in addition to customizing features of the swappable pre-amplifier 250. Further yet, some pre-amplifiers 250 may include a swappable configuration module 251 that may be a memory card with audio profile information. The pre-amplifier 250 may be implement specific configurable specifications based on data stored in the swappable memory card 251.

A pre-amplifier 250 will have a profile that defines how the initial electrical signal received from the pick-ups allows a musician to gain or reduce predefined frequencies to alter the signal's output, thereby changing the shape of the audio spectrum of an output signal. Various pre-amplifier 250 manufactures have configured how these pre-amplifiers 250 change tone, filter frequencies, affect gain, and other audio spectrum aspects. Some provide a lot of boost/cutting while others provide more refined control. Likewise, pre-amplifier 250 manufactures change the frequency breakpoints and range differently. All this makes for a wide variety of audio control and shaping for each preamp 250.

FIG. 3 is a view of the body portion 201 of the stringed instrument 200 having a cavity 235 that exhibits a removed electronic pre-amplifier 250 that governs the electronic pickups of the stringed instrument 200 according to an embodiment of the subject matter disclosed herein. As shown here, the electronic pre-amplifier 250 has been removed from the 19-pin connector 257 and has been set aside from the instrument 200. This state is ready now for the instrument 200 to receive a second electronic pre-amplifier (not shown) to be swapped into the audio output chain at the 19-pin connector 257. In this view, one can more readily see a metallic lining 236 disposed over an interior contour of the cavity 235 that is configured to inhibit electromagnetic signals from interfering with circuitry disposed in the cavity 235.

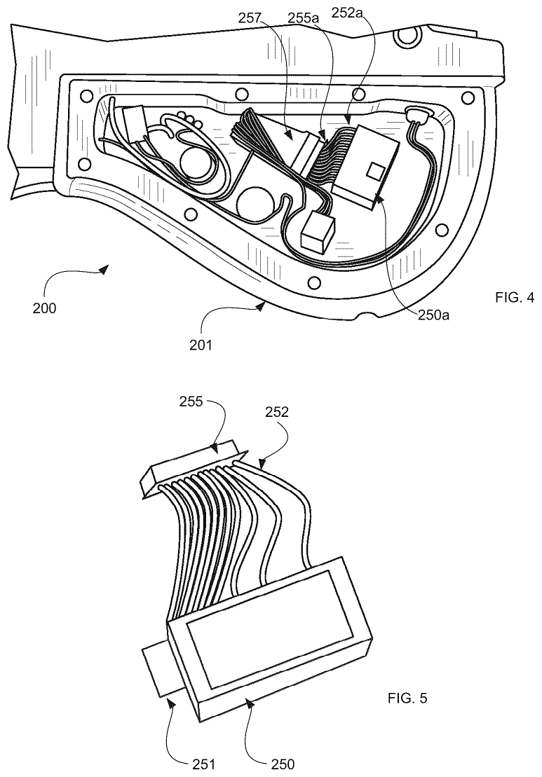

FIG. 4 is a view of a portion of stringed instrument body 200 having a cavity 235 to enclose a second, different, electronic pre-amplifier 250a that can be changed to alter the electronic circuit that governs the electronic pickups and other electronic circuitry of the stringed instrument according to an embodiment of the subject matter disclosed herein. This is similar to the depiction in FIG. 2 except that a different electronic pre-amplifier 250a is engaged thereby altering the audio output chain in a different manner. As such, the swappable pre-amplifier 250a includes a respective harness 252a and a respective connector 255 for interfacing with the instrument circuit the 19-pin connector 257.

FIG. 5 is diagram of an electronic pre-amplifier 250 that may be swapped in and out of the cavity 235 depicted in FIGS. 2-4 according to an embodiment of the subject matter disclosed herein. Here, one can see a standalone electronic pre-amplifier 250 that can be swapped in and out of an instrument suited to receive the connector 255 (coupled to the harness 252) of the 19-pin electronic pre-amplifier 250 that can be used to impart a specifically desired transfer function to the audio output chain of the instrument. The form factor here is small enough to be easily handled and swapped into a cavity 235 at the rear of a suited electric instrument (e.g., and electric guitar, an electric bass guitar, and the like). Further, the number of pins does not need to be 19. Other embodiments may have a different number of pins in the coupler ranging from 9 to 50.

Additionally, one can see the removable analog card 251 of the swappable pre-amplifier 250 suited to store specific configuration files for the pre-amplifier 250. Further, in other embodiments, the swappable pre-amplifier may be a specific form factor that is magnetically secured in place my magnets mounted in a housing that encompasses the circuitry of the pre-amplifier. This module may have exterior mounted pin connector for interfacing with a receptacle connector mounted to a cavity in the body of the instrument. In one embodiment, the pin-module interface comprises 24 pins, but may be more or fewer in different embodiments. Further, the instrument cavity may also include magnets for aligning and securing the swappable module in place. In still further embodiments, the module may be secured via pressure-fit connectors, clip-on connectors, screw-on connectors, bolt-on, hook and loop connectors and the like. These swappable module form factor embodiments are discussed further with respect to FIGS. &a-&c below.

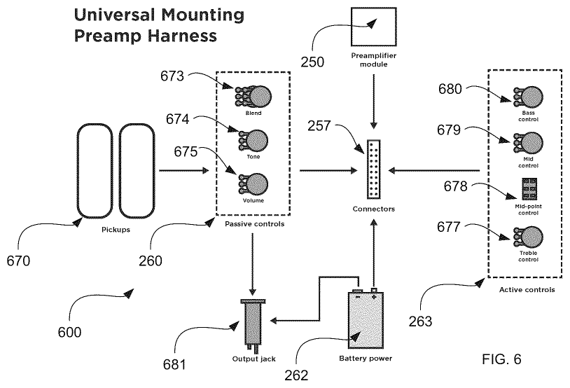

FIG. 6 is a hybrid block and schematic diagram 600 of the swappable and configurable pre-amplifier system according to an embodiment of the subject matter disclosed herein. Sometimes, this overall set of electronic componentry is called the harness 600. In this block diagram, one can see two sets of electrical pickups that may be disposed near strings (not shown in this block diagram). In this example embodiment, the underlying musical instrument may be an electric bass guitar, but a skilled artisan understands that any electric stringed instrument may utilize the swappable electronic pre-amplifier features detailed herein. The entire block diagram may be considered the audio output circuit such that the circuit includes an electrical pickup interface for facilitating the transmission of each individual pickup signal to additional signal processing componentry.

The additional componentry shown in FIG. 6 includes passive controls 260 that include blend 673, tone 674, and volume 675. Such passive controls are sometimes called analog signal controls in that no componentry involves digital signal processing that may require a battery-powered DSP circuit. Nonetheless, the system includes a battery 262 for providing active power to the swappable and configurable pre-amplifier 250 to the extent active controls (e.g., DSP) that may be coupled to the passive controls 260 and audio output circuit through a pre-amplifier module interface 257 (e.g., a 19-pin connector, in this embodiment). The system may further include active controls 263 such as bass-frequency control 680, mid-frequency control 679, mid-frequency center-point control 678, and treble (high)-frequency control 677. The harness 600 may culminate in an audio output which may be a ¼″ audio jack 681 for an instrument cable. In other embodiments, the audio output chain may culminate in a Bluetooth or other wireless output means (not shown).

As shown in FIG. 6, the harness 600 may also include a volume attenuator (e.g., volume control 675) and may also include a swappable band pass filter (e.g., frequency-attenuating tone control 674. Additional controls may also be present in the harness 600 in circuitry encompassed within the cavity. As differently profiled pre-amplifiers are easily swapped in and out here, different transfer functions may alter the audio output of the audio chain in a desired manner. That is, when vibrations are detected by the electrical pick-ups 670, an electrical signal is generated by the transducers in the electrical pick-ups 670. Then, as the initial electrical signals are passed through the swapped-in pre-amplifier 250, they are altered according to the transfer function of the swapped-in pre-amplifier 250.

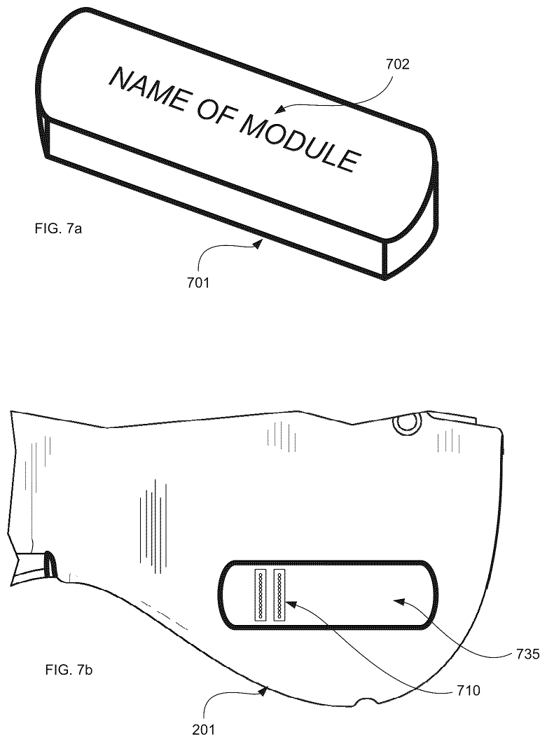

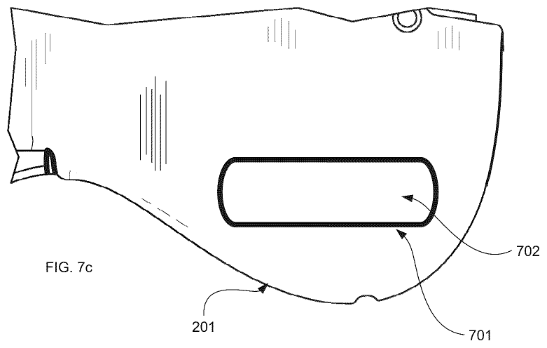

FIG. 7a-7c are schematic diagrams of three different examples of swappable and configurable pre-amplifiers 700a-c coupled through a 19-pin pre-amplifier module interface 257 to the harness 600 of a musical instrument according to embodiments of the subject matter disclosed herein. The example embodiments in these three examples include use of third-party pre-amplifiers 250 being altered to include a universal 19-pin interface for swapping into a suitably configured audio chain of a musical instrument.

FIG. 7a is diagram of a swappable modular pre-amplifier in a form factor suitable to be inserted into a cavity of a musical instrument according to an embodiment of the subject matter disclosed herein. In this embodiment, a swappable and configurable pre-amplifier comprises a form factor 701 that is suited to be inserted into a cavity of the same size as the form factor 701. The swappable pre-amplifier module may include a name 702 for identification on a top side and may also include a one or more pin-interfaces (not shown in this view) on the bottom side for simple insertion and interface with an instrument.

FIG. 1B is a diagram of a body portion 201 of a musical instrument having a suitably-sized cavity 735 for hosting the swappable and configurable pre-amplifier form factor of FIG. 7a according to an embodiment of the subject disclosed herein. In this cavity 735, one can see two different 12-pin connector receptacles for interfacing with similar-sized 12-pin connectors 710 mounted to a bottom facing side of a swappable and configurable pre-amplifier form factor 701, such as the one shown in FIG. 1a As mentioned before, the cavity 735 and the pre-amplifier form factor 701 may be secured to interface each other using magnetic elements or may use other means of securing such as pressure-fit connectors, clip-on connectors, screw-on connectors, bolt-on connectors, hook and loop connectors, and the like.

FIG. 7c is a diagram of a body portion 201 of a musical instrument having a suitably-sized cavity 735 for hosting the swappable and configurable pre-amplifier form factor of FIG. 7a with the pre-amplifier form factor 701 inserted according to an embodiment of the subject disclosed herein. As such, the pre-amplifier may be part of the signal chain of the instrument and the name 702 of the pre-amplifier can be seen when inserted.

The use of the terms “a” and “an” and “the” and similar referents in the specification and in the following claims are to be construed to cover both the singular and the plural, unless otherwise indicated herein or clearly contradicted by context. The terms “having,” “including,” “containing” and similar referents in the specification and in the following claims are to be construed as open-ended terms (e.g., meaning “including, but not limited to,”) unless otherwise noted. Recitation of ranges of values herein are merely indented to serve as a shorthand method of referring individually to each separate value inclusively falling within the range, unless otherwise indicated herein, and each separate value is incorporated into the specification as if it were individually recited herein. All methods described herein can be performed in any suitable order unless otherwise indicated herein or clearly contradicted by context. The use of any and all examples, or exemplary language (e.g., “such as”) provided herein, is intended merely to better illuminate embodiments and does not pose a limitation to the scope of the disclosure unless otherwise claimed, No language in the specification should be construed as indicating any non-claimed element as essential to each embodiment of the present disclosure.

Different arrangements of the components depicted in the drawings or described above, as well as components and steps not shown or described are possible. Similarly, some features and sub-combinations are useful and may be employed without reference to other features and sub-combinations. Embodiments have been described for illustrative and not restrictive purposes, and alternative embodiments will become apparent to readers of this patent. Accordingly, the present subject matter is not limited to the embodiments described above or depicted in the drawings, and various embodiments and modifications can be made without departing from the scope of the claims below.

That which is claimed is:

1. A musical instrument, comprising:
an instrument body having a cavity configured to receive a swappable pre-amplifier module;
at least one set of electrical pickups positioned to detect vibrations from an adjacent respective string, the at least one set of electrical pickups configured to generate an electrical signal in response to string vibrations;
a pre-amplifier module interface disposed in the cavity and configured to electrically couple to a pre-amplifier module that may be swapped in and out of the cavity;
a pre-amplifier module coupled to the pre-amplifier module interface and configured to alter the electrical signal from the at least one set of pickups; and
an audio output circuit coupled to the pre-amplifier module and configured to provide the altered electrical signal to an output jack.

2. The musical instrument of claim 1, wherein the pre-amplifier module interface comprises a 19-pin electrical connector.

3. The musical instrument of claim 1, wherein the pre-amplifier module further comprises:
a first set signal processing device suited to alter the received electrical signal in frequencies at a high end of a human range of hearing;
a second signal processing device suited to alter the received electrical signal in frequencies at a low end of the human range of hearing; and
a third signal processing suited to alter the received electrical signal in frequencies between the high end and the low end of the human range of hearing.

4. The musical instrument of claim 3, further comprising an adjustment device for adjusting a center frequency of the third signal processing device.

5. The musical instrument of claim 1, further comprising a volume attenuation device coupled to the audio output circuit and configured to alter the amplitude of the altered electrical signal.

6. The musical instrument of claim 1, further comprising at least one second set of electrical pickups positioned to detect vibration from the adjacent respective strings, the at least one second set of electrical pickups configured to generate a second electrical signal in response to string vibrations.

7. The musical instrument of claim 1, further comprising a battery disposed in the cavity and configured to provide electrical power to the pre-amplifier module through the pre-amplifier module interface.

8. The musical instrument of claim 1, further comprising a cover plate secured to cover the cavity using a plurality of magnetic fasteners.

9. The musical instrument of claim 1, further comprising a metallic lining disposed over an interior contour of the cavity and configured to inhibit electromagnetic signals from interfering with circuitry disposed in the cavity.

10. The musical instrument of claim 1, further comprising a wireless communication module electrically coupled to the pre-amplifier module and configured to receive remote signals from a remote computing device to adjust a manner in which electrical signals from the electrical pickups are altered.

11. A stringed instrument system, comprising:
an instrument body having a cavity configured to receive a swappable pre-amplifier module;
a plurality of strings secured between a head and the body along a neck that is attached to the body;
at least one set of electrical pickups positioned in the body and adjacent to the strings, the electrical pickups configured to detect vibrations from an adjacent respective string, the at least one set of electrical pickups configured to generate an electrical signal in response to string vibrations;
a pre-amplifier module interface disposed in the cavity and configured to electrically couple to at least two different pre-amplifier modules that may be swapped in and out of the cavity;
a first pre-amplifier module configured to couple to the pre-amplifier module interface and configured to after the electrical signal from the at least one set of pickups in a first manner;
a second pre-amplifier module configured to couple to the pre-amplifier module interface and configured to alter the electrical signal from the at least one set of pickups in a second manner that is different than the first manner; and
an audio output circuit coupled to the pre-amplifier module is swapped in and configured to provide the altered electrical signal to an output jack.

12. The stringed instrument system of claim 11, wherein the first pre-amplifier module further comprises:
a first set signal processing device suited to alter the received electrical signal in frequencies at a high end of a human range of hearing;
a second signal processing device suited to alter the received electrical signal n frequencies at a low end of the human range of hearing; and
a third signal processing suited to alter the received electrical signal in frequencies between the high end and the low end of the human range of hearing.

13. The stringed instrument system of claim 11, further comprising at least one second set of electrical pickups disposed in the body and positioned to detect vibrations from the adjacent respective strings, the at least one second set of electrical pickups configured to generate a second electrical signal in response to string vibrations.

14. The stringed instrument system of claim 11, further comprising a battery disposed in the cavity and configured to provide electrical power to the swapped-in pre-amplifier module through the pre-amplifier module interface.

15. The stringed instrument system of claim 11, further comprising a cover plate secured to cover the cavity using a plurality of magnetic fasteners.

16. The stringed instrument system of claim 11, further comprising a metallic lining disposed over an interior contour of the cavity and configured to inhibit electromagnetic signals from interfering with circuitry disposed in the cavity.

17. The stringed instrument system of claim 11, further comprising a wireless communication module electrically coupled to the swapped-in pre-amplifier module and configured to receive remote signals from a remote computing device to adjust a manner in which electrical signals from the electrical pickups are altered.

18. A method of configuring a musical instrument, comprising:
in a stringed musical instrument, removing a cover plate from a body of the stringed instrument to reveal circuitry that includes a first pre-amplifier that is connected to a set of electrical pickups positioned next to a set of strings and configured to generate electrical signals in response to string vibrations such that the first pre-amplifier alters the electrical signal in a first manner;
removing the first pre-amplifier from the cavity; and
swapping in a second pre-amplifier and connecting the second pre-amplifier to the set of electrical pickups positioned next to the set of strings, the second pre-amplifier configured to generate electrical signals in response to string vibrations such that the electrical signal is altered in a second manner by the second pre-amplifier.

19. The method of claim 18, wherein:
the first pre-amplifier is removed from a 19-pin pre-amplifier module interface disposed in the cavity and configured to electrically couple to the first pre-amplifier module to circuitry for the stringed instrument; and
the second pre-amplifier is inserted to couple with the 19-pin pre-amplifier module interface and configured to electrically couple to the second pre-amplifier module to circuitry for the stringed instrument.

20. The method of claim 18, further comprising:
receiving a wireless control signal from a remote computing device communicatively coupled to the second pre-amplifier; and
adjusting the second manner in which the second pre-amplifier alters the electrical signal in response to the wireless control signal.
